(19) United States
(12) Patent Application Publication
(10) Pub. No.: US 2026/0299178 A1
(43) Pub. Date: Oct. 1, 2026

(54) IMAGE DISTORTION PREVENTION FILTER AND MANUFACTURING METHOD THEREOF

(71) Applicant: Vault Creation Co., Ltd., Seoul (KR)

(72) Inventor: Sang Jun CHOI, Seoul (KR)

(73) Assignee: Vault Creation Co., Ltd., Seoul (KR)

(21) Appl. No.: 19/479,233

(22) PCT Filed: Apr. 25, 2024
(86) PCT No.: PCT/KR2024/005589

§ 371 Date: Oct. 27, 2025

(30) Foreign Application Priority Data
Apr. 25, 2023 (KR) 10-2023-0053994

(51) Int. Cl. G02B 5/28

(52) U.S. Cl. CPC G02B 5/285

(57) ABSTRACT

The present invention relates to an image distortion prevention filter in which a pattern having an irregular shape is formed on a transparent substrate, and a manufacturing method thereof. According to the present invention, formation of a metal pattern having an irregular shape on a transparent substrate may have an effect of preventing glare caused by a periodic pattern and blocking light diffraction and interference, thereby preventing image distortion.

### CROSS-REFERENCE TO RELATED APPLICATIONS

This application is a national stage entry of International Application No. PCT/KR2024/005589, filed Apr. 25, 2024, which claims priority to and the benefits of Korean Patent Application No. 10-2023-0053994, filed Apr. 25, 2023, in the Korean Intellectual Property Office under 35 U.S.C. §§ 119(a), 365(b), the entire contents of which are incorporated herein by reference.

### BACKGROUND

### 1. Technical Field

The present disclosure relates to a filter for preventing the distortion of an image and a method of manufacturing the same, and more particularly, to a filter for preventing the distortion of an image and a method of manufacturing the same, which are implemented to prevent the distortion of an image by forming a pattern having an irregular shape on a transparent substrate so that the diffraction and interference phenomena of light are blocked.

### 2. Description of Related Art

When a camera for capturing an image is exposed to an external environment, the image is distorted because rainwater is formed on a surface of a lens depending on external weather conditions or drops of steam are formed on a surface of the lens due to fog, etc. When a charged coupled device (CCD) or a CMOS image sensor (CIS) is applied to the front or rear camera or side mirror of a vehicle, if such a phenomenon occurs, it is difficult for a driver to perform safe driving because the driver cannot discern a surrounding vehicle or obstacle.

The distortion phenomenon of an image attributable to such rainwater or vapor is a phenomenon in which light is diffracted or subjected to interference in several directions due to rainwater adhering to the lens or a front window.

Conventionally, in order to solve such problems, a method of removing the distortion of an image by rainwater or vapor that is spread at a constant thickness by installing a filter on which a fine metal pattern is formed at the front of a lens has been carried out.

FIG. 1 is a diagram illustrating a conventional filter having a regular pattern.

Referring to FIG. 1, a conventional filter 100 includes a transparent substrate 110 and a metal pattern 120 having conductive metal deposited on one surface of the substrate 110 to form a regular structure.

However, the conventional filter, such as that illustrated in FIG. 1, has good wettability for water because the metal pattern has periodical regularity, but has problems in that an image is distorted and resolution is badly affected because light spreading attributable to the interference and diffraction of light occurs.

FIG. 2 is a diagram illustrating a conventional filter having an irregular pattern.

A filter 200 illustrated in FIG. 2 includes a hub-spoke-shaped metal pattern formed on a transparent substrate 210. The metal pattern includes circular hubs 221 each having a constant diameter and a straight line-shaped spoke 222 that connects the circular hubs, and has a form in which the circular hubs and the spokes are disorderly connected.

When a metal pattern having such a form is used, the diffraction or interference of light tends to be partially reduced, but there is still a problem in that a diffraction or interference phenomenon having a specific form occurs due to a circle having a constant diameter.

FIG. 3 is a diagram illustrating another conventional filter having an irregular pattern.

A filter 300 illustrated in FIG. 3 includes an oval metal pattern 320 having various shapes, which is formed on a transparent substrate 310. In FIG. 3, a circle having a constant diameter is not used, a spoke that connects circles is obviated, and a metal pattern 320 having an oval shape is formed. In this case, the oval shapes overlap and the size and location of an oval and the ratio of a long axis and a short axis are disordered in order to reduce diffraction and interference phenomena.

However, it is inconvenient to practically implement such a metal pattern, and the metal pattern has a problem in that the distortion of an image still occurs because it is difficult to fully remove a degree of disorderness in the shape of the pattern.

The background provided herein is for the purpose of generally presenting the context of the disclosure. Work of the presently named inventors, to the extent that it is described in this background section, as well as aspects of the description that may not otherwise qualify as prior art at the time of filing, are neither expressly nor impliedly admitted as prior art against the disclosure.

### SUMMARY

The present disclosure has been made to solve such problems, and an object of the present disclosure is to provide a filter for preventing the distortion of an image and a method of manufacturing the same, which are implemented to prevent the distortion of an image by forming a metal layer including a pattern having an irregular shape on a transparent substrate so that the diffraction and interference phenomena of light are blocked.

Additional aspects will be set forth in the detailed description, which follows, and in part, will be apparent from the disclosure, or may be learned by practice of the disclosed embodiments and/or the claimed subject matter.

A filter for preventing the distortion of an image according to the present disclosure includes a transparent substrate and a metal layer including a metal pattern having an irregular shape and formed by depositing conductive metal on one surface of the substrate. The diffraction and interference phenomena of light are blocked by an irregular structure of the pattern.

A method of manufacturing a filter for preventing the distortion of an image according to the present disclosure includes a pattern mask generation step of generating a pattern mask including a pattern having an irregular shape, a substrate preparation step of preparing a transparent substrate, and a metal layer forming step of forming a metal layer including the pattern having the irregular shape on the transparent substrate.

According to the filter for preventing the distortion of an image according to the present disclosure, there are effects in that diffraction and interference phenomena of light are blocked and thus the distortion of an image can be prevented because light spreading attributable to a periodical pattern is prevented by forming the metal pattern having an irregular shape on the transparent substrate.

According to the filter for preventing the distortion of an image according to the present disclosure, there are advantages in that it is very easy to change the period, amplitude, and phase of a sine curve or a cosine curve according to a trigonometric function and a degree of the distortion of an image can be greatly reduced because a degree of disorderness is further higher than that of the existing disordered pattern.

The foregoing general description and the following detailed description are illustrative and explanatory and are intended to provide further explanation of the claimed subject matter.

### BRIEF DESCRIPTION OF DRAWINGS

Various embodiments disclosed herein are illustrated by way of example, and not by way of limitation, in the figures of the accompanying drawings, in which like reference numerals and/or characters refer to similar elements.

FIG. 1 is a diagram illustrating a conventional filter having a regular pattern.

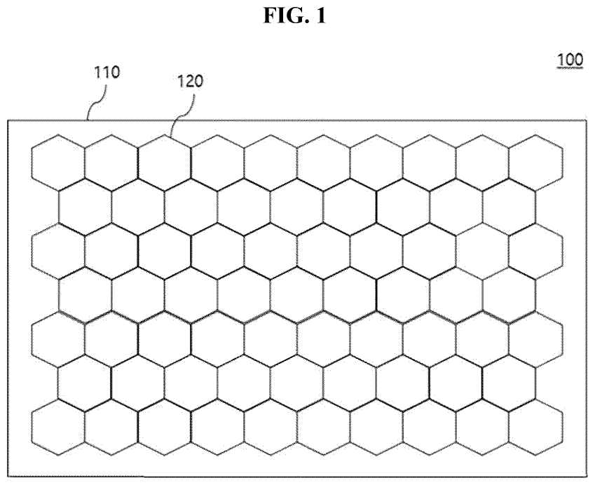

FIG. 2 is a diagram illustrating a conventional filter having an irregular pattern.

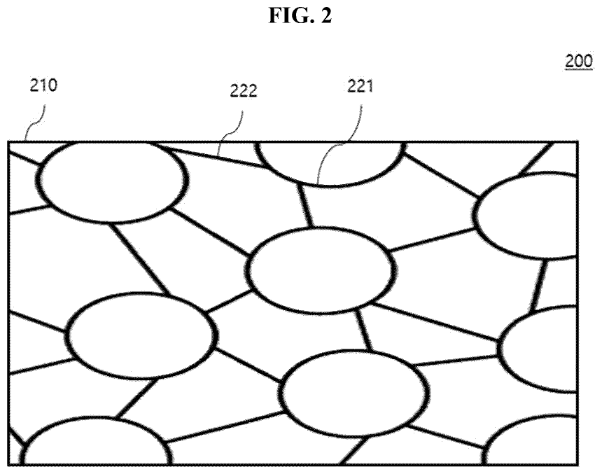

FIG. 3 is a diagram illustrating another conventional filter having an irregular pattern.

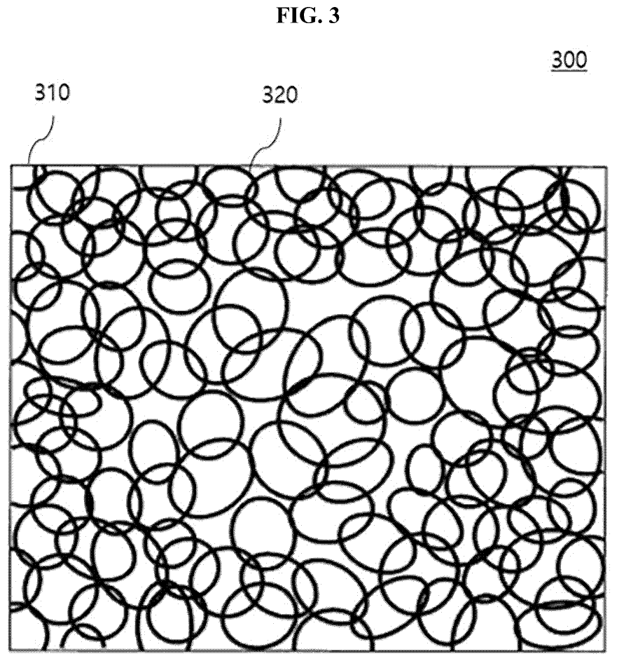

FIG. 4 is a schematic cross-sectional view of a filter for preventing the distortion of an image according to an embodiment of the present disclosure.

FIG. 5 is a diagram illustrating an embodiment of a plan view viewed in a direction A-A′ of FIG. 4.

FIG. 6 is a diagram illustrating another embodiment of the plan view viewed in the direction A-A′ of FIG. 4.

FIG. 7 is a diagram illustrating another embodiment of the plan view viewed in the direction A-A′ of FIG. 4.

FIG. 8 is a diagram illustrating another embodiment of the plan view viewed in the direction A-A′ of FIG. 4.

FIG. 9 is a process flowchart of an embodiment of a method of manufacturing a filter for preventing the distortion of an image according to the present disclosure.

FIGS. 10A, 10B, 10C, 10D, 10E, and 10F are diagrams for describing a metal layer forming step of the method of manufacturing a filter for preventing the distortion of an image according to the present disclosure.

### DETAILED DESCRIPTION OF THE EMBODIMENTS

Advantages and characteristics of the present disclosure and a method for achieving the advantages and characteristics will become apparent from embodiments described in detail later in conjunction with the accompanying drawings. However, the present disclosure is not limited to the disclosed embodiments, but may be implemented in various different forms. The embodiments are merely provided to complete the present disclosure and to fully notify a person having ordinary knowledge in the art to which the present disclosure pertains to the category of the present disclosure. The present disclosure is merely defined by the category of the claims. The same reference numeral denotes the same component unless separately specified.

In the following description, for the purposes of explanation, numerous specific details are set forth to provide a thorough understanding of various embodiments or implementations. The terms “embodiments” and “implementations” may be used interchangeably to describe one or more non-limiting examples of systems, apparatuses, methods, etc., described herein. It is apparent, however, that various embodiments may be practiced without these specific details or with one or more equivalent arrangements. In other instances, known structures and devices are shown in block diagram form to avoid unnecessarily obscuring various embodiments. Further, various embodiments may be different, but do not have to be exclusive. For example, specific shapes, configurations, and characteristics of an embodiment may be used or implemented in another embodiment without departing from the teachings of the disclosure.

Unless otherwise specified, the illustrated embodiments are to be understood as providing example features of varying detail of some embodiments. Thus, unless otherwise specified, the aspects, components, features, modules, regions, structures, units, etc. (hereinafter individually or collectively referred to as an “element” or “elements”), of the various illustrations may be otherwise combined, separated, interchanged, and/or rearranged without departing from the teachings of the disclosure.

In the accompanying drawings, the size and relative sizes of elements may be exaggerated for clarity and/or descriptive purposes. As such, the sizes and relative sizes of the respective elements are not necessarily limited to the sizes and relative sizes shown in the drawings. In a case that an embodiment may be implemented differently, a specific process order may be performed differently from the described order. For example, two consecutively described processes may be performed substantially at the same time or performed in an order opposite the described order. Also, like reference numerals and/or reference characters denote like elements.

In a case that an element, such as a structure, is referred to as being “on,” “over,” “connected to (or with),” or “coupled to (or with)” another element, it may be directly on, directly over, directly connected to (or with), or directly coupled to (or with) the other element or at least one intervening element may be present. However, in a case that an element is referred to as being “directly on,” “directly over,” “directly connected to (or with),” or “directly coupled to (or with)” another element, there are no intervening elements present. Other terms and/or phrases, if used herein, to describe a relationship between elements should be interpreted in a like fashion, such as “between” versus “directly between,” “adjacent” versus “directly adjacent,” “on” versus “directly on,” “contacting” versus “directly contacting,” “touching” versus “directly touching,” etc. Further, the term “connected” may refer to physical, electrical, and/or fluid connection.

For the purposes of this disclosure, if used herein, the phrases “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. Also, if used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.”

Spatially relative terms, such as “beneath,” “below,” “under,” “lower,” “above,” “upper,” “over,” “higher,” “side” (e.g., as in “sidewall”), and the like, may be used herein for descriptive purposes, and thereby, to describe one element's spatial relationship to at least one other element as illustrated in the drawings. Spatially relative terms are intended to encompass different orientations of, for instance, an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Further, the apparatus may be otherwise oriented (e.g., rotated 90 degrees or at other orientations), and as such, the spatially relative descriptors used herein interpreted accordingly.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in and of itself, as necessarily encompassing a plurality of items—it is to be understood that a set or a subset can encompass only one member or multiple members (unless the context indicates otherwise).

The terms “comprises,” “comprising,” “includes,” “including,” “has,” “have,” and/or “having” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, if used herein, the terms “substantially,” “about,” “approximately,” and other similar terms, are used as terms of approximation and not as terms of degree, and as such, are utilized to account for inherent deviations in measured, calculated, and/or provided values that would be recognized by one of ordinary skill in the art. Accordingly, the terms “substantially,” if used herein, and unless otherwise specified, may mean within 5% of a referenced value. For example, substantially perpendicular may mean within ±5% of being parallel. The terms “about” and “approximately,” if used herein, and unless otherwise specified, may mean within one or more standard deviations, such as within ±30%, ±20%, ±10%, or ±5% of a stated value. Moreover, the term “between,” if used herein in association with a range of values, is to be understood, unless otherwise indicated, as being inclusive of the start and end values of the range. For example, between 1 and 5 is to be understood as being inclusive of the numbers 1, 2, 3, 4, and 5, not just the numbers 2, 3, and 4. Furthermore, the expression “being the same” may mean “being substantially the same.” For instance, the expression “being the same” may include a range that can be tolerated by those skilled in the art. Other expressions may also be expressions from which “substantially” has been omitted.

As customary in the field, some embodiments may be described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and are not to be interpreted in an idealized or overly formal sense, unless expressly so defined herein.

Hereinafter, the present disclosure is described in detail with reference to the drawings.

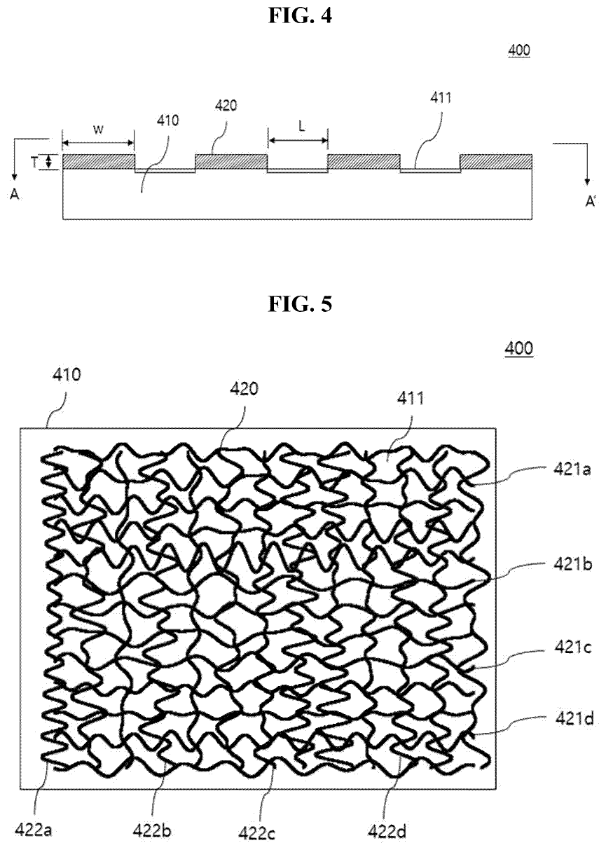

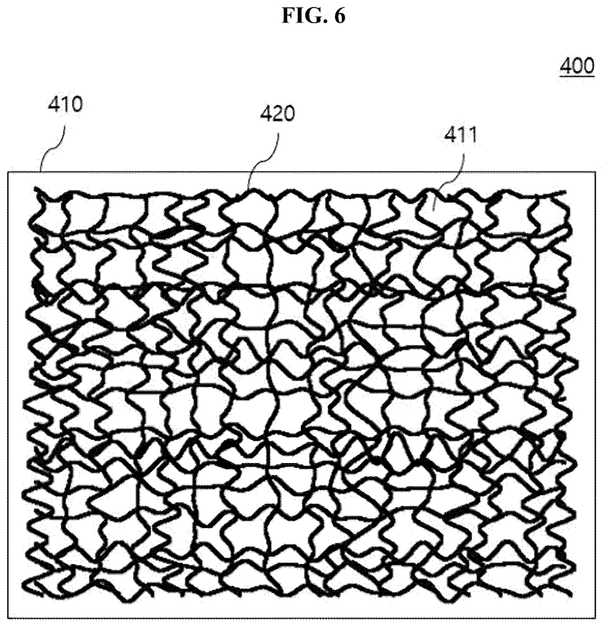

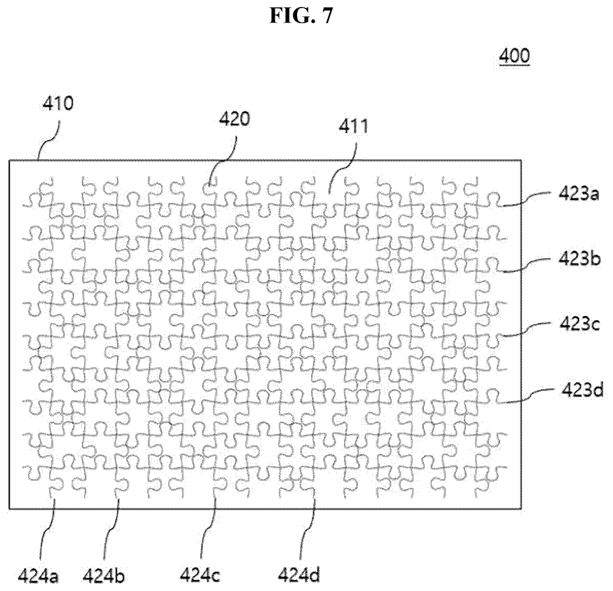

FIG. 4 is a schematic cross-sectional view of a filter for preventing the distortion of an image according to an embodiment of the present disclosure. FIGS. 5 and 6 are diagrams illustrating embodiments of a plan view viewed in the direction A-A′ of FIG. 4.

As illustrated in FIGS. 4 to 6, a filter 400 for preventing the distortion of an image according to an embodiment of the present disclosure includes a transparent substrate 410 and a metal layer 420 formed on one surface of the substrate 410 and including a metal pattern having an irregular shape.

In this case, the substrate 410 is transparent and may be glass, polymers or the like. The material may include one or more elements, selected among SiO2 and Al2O3. Furthermore, the substrate 410 is not limited to the hard material, and may be a flexible material which may be deformed, such as a bending or folding material.

A material that is not corrosive in an external environment is preferably used as metal deposited on the transparent substrate 410, and the metal may include one or more elements, selected among Cr, Ni, Ti, TiN, and ITO.

Meanwhile, it is preferred that a surface of a non-metallization part 411 that belongs to an upper part of the transparent substrate 410 and in which the metal pattern is not formed is processed by using plasma. In the plasma processing, a part that belongs to the surface of the substrate 410 and in which the metal pattern is not formed is processed by using RF plasma in a vacuum state.

When the part 411 that belongs to the surface of the substrate 410 and in which the metal pattern is not formed is subjected to plasma processing as described above, there is an effect in that wettability for rainwater or fine water droplets can be improved.

The filter for preventing the distortion of an image according to the present disclosure includes the metal pattern having a disordered form and does not generate the phenomenon in which light is diffracted or subjected to interference in a constant direction. Accordingly, although the filter for preventing the distortion of an image is installed at the front of the lens of a camera, light spreading does not occur and the distortion of an image does not occur.

In the present disclosure, in order to generate such a disordered shape, the wavelengths and amplitude of a sine curve and a cosine curve according to a trigonometric function are disorderly set a length direction thereof. Furthermore, an interval between the curves and an initial phase of each curve are disorderly set in order to improve a degree of disorderness in the metal pattern that is finally generated. That is, in the present disclosure, it is possible to adjust the degree of disorderness in the metal pattern that is finally formed by applying multiple degrees of disorderness.

As illustrated in FIG. 5, the metal pattern of a metal layer 420 of the filter 400 for preventing the distortion of an image according to an embodiment of the present disclosure has a form in which sine curve lines using a trigonometric function are combined. That is, the metal pattern having an irregular shape is formed by a combination of sine curve lines 421a, 421b, 421c, 421d, . . . that are horizontally formed and sine curve lines 422a, 422b, 422c, 422d, . . . that are vertically formed.

In this case, the irregularity of the metal pattern can be increased by applying various parameters to the sine curve lines 421a, 421b, 421c, 421d, . . . that are horizontally formed and the sine curve lines 422a, 422b, 422c, 422d, . . . that are vertically formed.

That is, the irregularity of the metal pattern may be increased by disorderly changing the number of sine curve lines that are horizontally or vertically formed, an interval between the sine curve lines that are horizontally or vertically formed, the period of the sine curve line, amplitude of the sine curve line, the phase of the sine curve line, and the width W and thickness T of the sine curve line.

The curve line using the trigonometric function has been described as being a sine curve line, but it is natural that the curve line may also be applied to a cosine curve line.

FIG. 6 illustrates a metal pattern that is generated by further increasing a degree of disorderness compared to the case of FIG. 5. The present disclosure has an advantage in that a degree of disorderness can be adjusted as described.

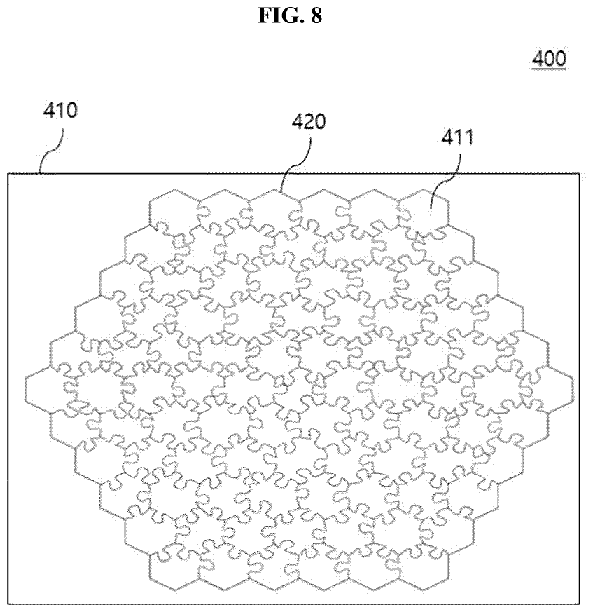

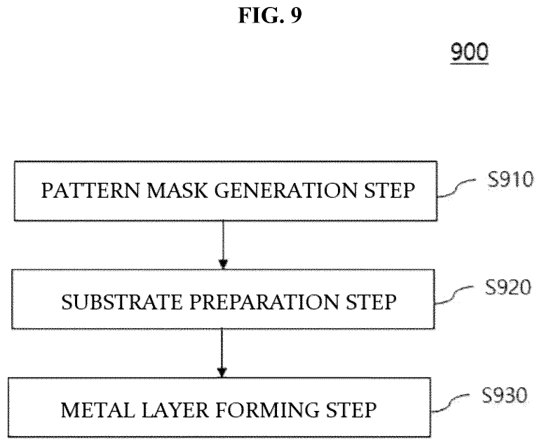

FIGS. 7 and 8 are diagrams illustrating other embodiments of the plan view viewed in the direction A-A′ of FIG. 4.

FIGS. 5 and 6 illustrate that the irregular pattern is formed by using the sine curve lines using the trigonometric function with respect to the metal layer of the filter for preventing the distortion of an image. In contrast, FIGS. 7 and 8 illustrate that a jigsaw pattern is formed by using jigsaw lines.

As illustrated in FIG. 7, the metal pattern of the metal layer 420 of the filter 400 for preventing the distortion of an image according to an embodiment of the present disclosure has a form of the jigsaw pattern having a combination of a the plurality of jigsaw lines and having an irregular shape. That is, the metal pattern having an irregular shape is formed by a combination of jigsaw lines 423a, 423b, 423c, 423d, . . . that are horizontally formed and jigsaw lines 424a, 424b, 424c, 424d, . . . that are vertically formed.

In this case, the irregularity of the metal pattern may be increased by randomly changing the number of jigsaw lines, an interval between the jigsaw lines, the period of the jigsaw line, amplitude of the jigsaw line, and the width and thickness of the jigsaw line with respect to the jigsaw lines 423a, 423b, 423c, 423d, . . . that are horizontally formed and the jigsaw lines 424a, 424b, 424c, 424d, . . . that are vertically formed.

FIG. 8 illustrates the metal pattern that is generated in a hexagon form and that has a degree of disorderness further increased compared to the case of FIG. 7. The present disclosure has an advantage in that the degree of disorderness can be adjusted as described.

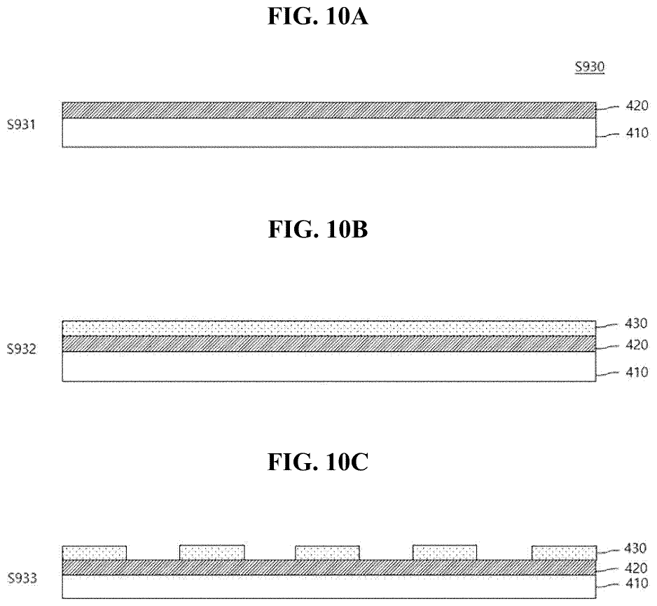

FIG. 9 is a process flowchart of an embodiment of a method of manufacturing a filter for preventing the distortion of an image according to the present disclosure.

As illustrated in FIG. 9, a method 900 of manufacturing a filter for preventing the distortion of an image according to an embodiment of the present disclosure includes a pattern mask generation step S910, a substrate preparation step S920, and a metal layer forming step S930.

In the pattern mask generation step S910, a pattern mask including a pattern having an irregular shape is generated by randomly arranging a plurality of sine curve lines or a plurality of cosine curve lines by using a trigonometric function.

In this case, the irregularity of the metal pattern may be adjusted by randomly changing at least one of the number of plurality of sine curve lines or plurality of cosine curve lines, an interval between the curve lines, the period of the curve line, amplitude of the curve line, the phase of the curve line, and the width and thickness of the curve line.

Meanwhile, in the pattern mask generation step S910, the pattern mask including the pattern having the irregular shape may be generated by randomly arranging a plurality of jigsaw lines.

In this case, the irregularity of the metal pattern may be adjusted by randomly changing at least one of the number of jigsaw lines, an interval between the jigsaw lines, the period of the jigsaw line, amplitude of the jigsaw line, and the width and thickness of the jigsaw line.

In the substrate preparation step S920, after the pattern mask is generated, a substrate on which the metal pattern will be formed is prepared.

In the metal layer forming step S930, a metal layer including the pattern having the irregular shape is formed on a transparent substrate by using the pattern mask.

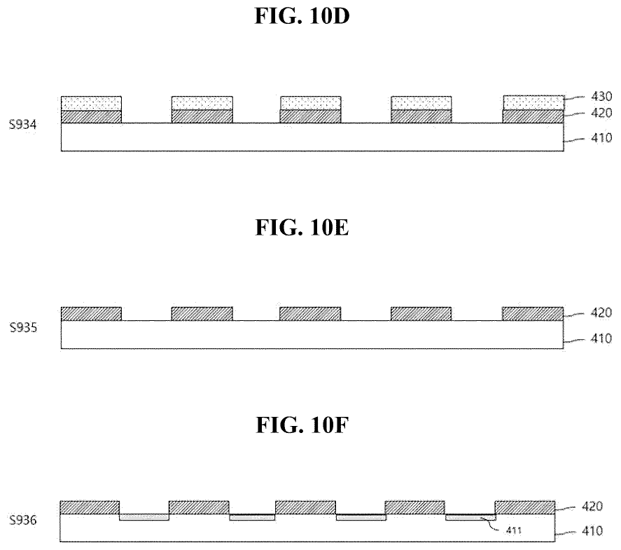

FIGS. 10A, 10B, 10C, 10D, 10E, and 10F are diagrams for describing the metal layer forming step of the method of manufacturing a filter for preventing the distortion of an image according to the present disclosure.

As illustrated in FIGS. 10A to 10F, the metal layer forming step S930 includes a metal layer deposition step S931, a photoresist application step S932, a photolithography step S933, a metal pattern forming step S934, a photoresist removal step S935, and a plasma processing step S936.

In the metal layer deposition step S931 (see FIG. 10A), the metal layer 420 is deposited by depositing metal on the transparent substrate 410. In this case, glass or flexible polymer may be used as the transparent substrate 410. The metal that is deposited on the transparent substrate 410 may include one or more elements, selected among Cr, Ni, Ti, TiN, and ITO.

In the photoresist application step S932 (see FIG. 10B), a photoresist 430 is applied on the metal layer 420.

In the photolithography step S933 (see FIG. 10C), after a pattern mask on which a pattern is formed is formed on the photoresist 430, light is radiated.

In the metal pattern forming step S934 (see FIG. 10D), a metal pattern is formed by etching the metal layer 420 through etching. In this case, it is preferred that dry etch is basically used as the etching.

In the photoresist removal step S935 (see FIG. 10E), the photoresist is removed according to a known method.

In the plasma processing step S936 (see FIG. 10F), plasma processing is performed on the part 411 that belongs to the transparent substrate 410 and in which the metal pattern is not formed by using RF plasma in a vacuum state. When the part that belongs to a surface of the substrate 410 and in which the metal pattern is not formed is subjected to plasma processing, there is an effect in that wettability for rainwater or fine water droplets can be improved.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered illustrative and not as restrictive, and embodiments are not to be limited to the details given herein.

What is claimed is:

1. A filter for preventing a distortion of an image, comprising:
a transparent substrate; and
a metal layer comprising a metal pattern having an irregular shape and formed by depositing conductive metal on one surface of the substrate,
wherein diffraction and interference phenomena of light are blocked by an irregular structure of the pattern.

2. The filter of claim 1, wherein the substrate comprises glass or flexible polymers.

3. The filter of claim 1, wherein a part that belongs to a surface of the substrate and in which the metal pattern is not formed is subjected to plasma processing.

4. The filter of claim 1, wherein a form of the metal pattern is the irregular shape by a combination of a plurality of sine curve lines or a plurality of cosine curve lines.

5. The filter of claim 4, wherein in the plurality of sine curve lines or the plurality of cosine curve lines that forms the metal pattern, a number of curve lines, an interval between the curve lines, a period of the curve line, amplitude of the curve line, a phase of the curve line, and a width and thickness of the curve line are randomly formed.

6. The filter of claim 1, wherein the metal pattern is a jigsaw pattern having an irregular shape by a combination of a plurality of jigsaw lines.

7. The filter of claim 6, wherein a width and thickness of each of the plurality of jigsaw lines that forms the metal pattern are randomly formed.

8. The filter of claim 1, wherein the metal that forms the metal pattern comprises one or more elements, selected among Cr, Ni, Ti, TiN, and ITO.

9. A method of manufacturing a filter for preventing a distortion of an image, the method comprising:
a pattern mask generation step of generating a pattern mask comprising a pattern having an irregular shape;
a substrate preparation step of preparing a transparent substrate; and
a metal layer forming step of forming a metal layer comprising the pattern having the irregular shape on the transparent substrate.

10. The method of claim 9, wherein:
the pattern mask generation step comprises forming a pattern mask comprising the pattern having the irregular shape by randomly arranging a plurality of sine curve lines or a plurality of cosine curve lines by using a trigonometric function, and
an irregularity of the metal pattern is adjusted by randomly changing at least one of a number of curve lines, an interval between the curve lines, a period of the curve line, amplitude of the curve line, a phase of the curve line, and a width and thickness of the curve line.

11. The method of claim 9, wherein:
the pattern mask generation step comprises generating the pattern mask comprising the pattern having the irregular shape by randomly arranging a plurality of jigsaw lines, and
the irregularity of the metal pattern is adjusted by randomly changing and applying at least one of a number of jigsaw lines, an interval between the jigsaw lines, a period of the jigsaw line, amplitude of the jigsaw line, and a width and thickness of the jigsaw line.

12. The method of claim 9, wherein the metal layer forming step comprises:
a metal layer deposition step of depositing a metal layer by depositing metal on the transparent substrate;
a photoresist application step of applying a photoresist on the deposited metal layer;
a photolithography step of radiating light to the photoresist after forming the pattern mask on which the irregular pattern is formed;
a metal pattern forming step of forming an irregular metal pattern by etching the metal layer through etching;
a photoresist removal step of removing the photoresist; and
a plasma processing step of performing plasma processing on a part that belongs to the transparent substrate and in which the metal pattern is not formed.

13. The method of claim 12, wherein the substrate comprises glass or flexible polymers.

14. The method of claim 12, wherein in the metal pattern forming step, the metal pattern is formed by a dry etch method.

15. The method of claim 10, wherein the metal layer forming step comprises:
a metal layer deposition step of depositing a metal layer by depositing metal on the transparent substrate;
a photoresist application step of applying a photoresist on the deposited metal layer;
a photolithography step of radiating light to the photoresist after forming the pattern mask on which the irregular pattern is formed;
a metal pattern forming step of forming an irregular metal pattern by etching the metal layer through etching;
a photoresist removal step of removing the photoresist; and
a plasma processing step of performing plasma processing on a part that belongs to the transparent substrate and in which the metal pattern is not formed.

16. The method of claim 15, wherein the substrate comprises glass or flexible polymers.

17. The method of claim 15, wherein in the metal pattern forming step, the metal pattern is formed by a dry etch method.
